(19) United States
(12) Patent Application Publication
(10) Pub. No.: US 2020/0313030 A1
(43) Pub. Date: Oct. 1, 2020

(54) METHOD OF MANUFACTURING SOLAR CELL FOR MANUFACTURING SOLAR CELL FROM SPLITTABLE SOLAR CELL THAT CAN BE SPLIT, SOLAR CELL, AND SOLAR CELL MODULE

(71) Applicant: PANASONIC CORPORATION, Osaka (JP)

(72) Inventor: Akiyoshi OGANE, Osaka (JP)

(21) Appl. No.: 16/816,128

(22) Filed: Mar. 11, 2020

(30) Foreign Application Priority Data
Mar. 27, 2019 (JP) 2019-061113

(51) Int. Cl. H01L 31/18; H01L 31/0352; H01L 31/20; H01L 31/0747

(52) U.S. Cl. CPC H01L 31/1868; H01L 31/0747; H01L 31/208; H01L 31/035272

(57) ABSTRACT

In a splittable solar cell, a first surface having a first conductivity type and a second surface including at least a portion of a second conductivity type different from the first conductivity type face opposite directions. The splittable solar cell like this is prepared. A dopant source of the of the first conductivity type is provided on the first surface of the splittable solar cell. The dopant source is irradiated with a laser.

### CROSS-REFERENCE TO RELATED APPLICATION

This application is based upon and claims the benefit of priority from the prior Japanese Patent Application No. 2019-061113, filed on Mar. 27, 2019, the entire contents of which are incorporated herein by reference.

### BACKGROUND

### 1. Field

The present disclosure relates to a technology of manufacturing a solar cell, and, in particular, to a method of manufacturing a solar cell for manufacturing a solar cell from a splittable solar cell that can be split, to a solar cell, and to a solar cell module.

### 2. Description of the Related Art

By way of one example, a solar cell is manufactured such that a thin film layer is formed on a semiconductor substrate, and laser irradiation is performed for heating (see, for example, JP59-56775).

When a solar cell made of crystalline silicon (Si), etc. is worked in laser splitting, a laser damage in the form of a crystal fault is formed on the split end face. A laser damage results in poor output characteristics.

### SUMMARY

The disclosure addresses the above-described issue, and a general purpose thereof is to provide a technology of inhibiting reduction in the output of power generation due to splitting.

The method of manufacturing a solar cell according to an embodiment of the present disclosure includes: preparing a splittable solar cell in which a first surface having a first conductivity type and a second surface including at least a portion of a second conductivity type different from the first conductivity type face opposite directions; providing a dopant source of the of the first conductivity type on the first surface of the splittable solar cell; and irradiating the dopant source with a laser.

Another embodiment of the present disclosure also relates to a method of manufacturing a solar cell. The method includes: preparing a splittable solar cell in which a first surface having a first conductivity type and a second surface including at least a portion of a second conductivity type different from the first conductivity type face opposite directions; and irradiating the first surface of the splittable solar cell with a laser while supplying a dopant gas of the first conductivity type to the first surface.

Still another embodiment of the present disclosure relates to a solar cell. The solar cell includes: a first surface having a first conductivity type; a second surface facing a direction opposite to a direction of the first surface and having at least a portion of a second conductivity type different from the first conductivity type; and a side surface provided between the first surface and the second surface. A first area is provided in a portion of the side surface toward the first surface, and a second area is provided in a portion toward the second surface, and a first impurity concentration of the first conductivity type in the first area is higher than a second impurity concentration of the first conductivity type in the second area.

Still another embodiment of the present disclosure relates to a solar cell module. The solar cell module includes a plurality of solar cells. Each of the plurality of solar cells includes: a first surface having a first conductivity type; a second surface facing a direction opposite to a direction of the first surface and having at least a portion of a second conductivity type different from the first conductivity type; and a side surface provided between the first surface and the second surface. A first area is provided in a portion of the side surface toward the first surface, and a second area is provided in a portion toward the second surface, and a first impurity concentration of the first conductivity type in the first area is higher than a second impurity concentration of the first conductivity type in the second area.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a top view showing a structure of a splittable solar cell according to an embodiment;

FIG. 2A-2C show an outline of the steps of manufacturing the solar cell;

FIG. 3 is a cross-sectional view showing a structure of the solar cell manufactured in the manufacturing steps of FIGS. 2A-2C;

FIGS. 4A-4D show specific examples of the steps of manufacturing the solar cell;

FIGS. 5A-5D show further specific examples of the steps of manufacturing the solar cell;

FIGS. 6A-6D show still further specific examples of the steps of manufacturing the solar cell;

FIGS. 7A-7D show still further specific examples of the steps of manufacturing the solar cell; and

FIGS. 8A-8C show a structure of a solar cell module including the solar cell of FIG. 3.

### DETAILED DESCRIPTION

The invention will now be described by reference to the preferred embodiments. This does not intend to limit the scope of the present invention, but to exemplify the invention.

A brief summary will be given before describing the present disclosure in specific details. The embodiment relates to a technology of splitting one solar cell into a plurality of cells. The one solar cell that is yet to be split will be called a “splittable solar cell”, and each of the plurality of solar cells after splitting will be called a “solar cell”. Normally, when a splittable solar cell is worked in laser splitting, a laser damage in the form of a crystal fault formed on the split end face makes the output characteristics poorer. A process of inactivating a defect on the split end face will be necessary to inhibit reduction in the output. Generally, laser splitting is performed after a surface collecting electrode of the splittable solar cell is formed. It is not easy to additionally perform an inactivation process on the split end face after the surface collecting electrode is formed, from the perspective of deterioration of the collecting electrode, etc. The inactivation process on the end face or the surface involves passivation or field-effect passivation. In passivation, an unattached active site is terminated by a hydrogen atom, etc. In field-effect passivation, a high doping concentration area is provided on the end face or the surface, and carriers generated by the band-bending effect (field effect) are repelled from the defective part. Both processes reduce the recombination loss and result in reduction in the internal potential loss of the solar cell.

In this embodiment, a high doping concentration area is formed on the split end face by performing laser doping concurrently with laser irradiation for splitting. Field-effect passivation in the high doping concentration area on the split end face inhibits reduction in the output. The terms “parallel” and “orthogonal” in the following description not only encompass completely parallel or orthogonal but also encompass slightly off-parallel and off-orthogonal within the margin of error. The term “substantially” means identical within certain limits. Hereafter, (1) the manufacturing steps, (2) specific examples, and (3) the structure of a solar cell module will be described in the stated order.

### (1) MANUFACTURING STEPS

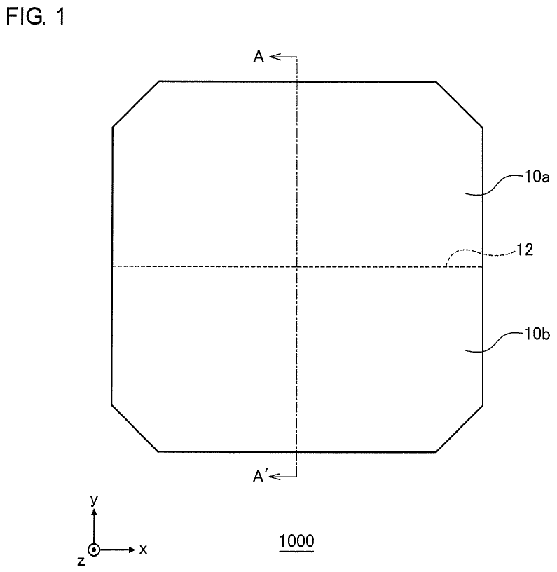

FIG. 1 is a top view showing a structure of a splittable solar cell 1000. As shown in FIG. 1, an orthogonal coordinate system including an x axis, y axis, and a z axis is defined. The x axis and y axis are orthogonal to each other in the plane of the splittable solar cell 1000. The z axis is perpendicular to the x axis and y axis and extends in the direction of thickness of the splittable solar cell 1000. The positive directions of the x axis, y axis, and z axis are defined in the directions of arrows in FIG. 1, and the negative directions are defined in the directions opposite to those of the arrows. Of the two principal surfaces forming the splittable solar cell 1000 that are parallel to the x-y plane, the principal surface disposed on the positive direction side along the z axis is the laser irradiation surface, and the principal surface disposed on the negative direction side along the z axis is the surface opposite to the laser irradiation surface (laser non-irradiation surface). Hereinafter, the positive direction side along the z axis will be referred to as “laser irradiation surface side” and the negative direction side along the z axis will be referred to as “laser non-irradiation surface side”. Whether the positive direction side along the z axis or the negative direction side receives light to generate electric power in the splittable solar cell and the solar cell is optional.

Thus, FIG. 1 shows a structure of the splittable solar cell 1000 from the laser irradiation surface side. The splittable solar cell 1000 is shaped such that the four corners of a square are chamfered straight. A splitting line 12 extending in the x-axis direction is provided at the center of the splittable solar cell 1000 in the y-axis direction. The splitting line 12 is a line along which the splittable solar cell 1000 is expected to be split. By splitting the splittable solar cell 1000 along the splitting line 12, a first solar cell 10a and a second solar cell 10b are formed. The first solar cell 10a and the second solar cell 10b are generically referred to as solar cells 10. The solar cell 10 has a rectangular shape that is longer in the x-axis direction than in the y-axis direction. The solar cell 10 is also called a half-cut cell. The shape of the splittable solar cell 1000, the arrangement of the splitting line 12, the shape and number of the solar cells 10 shown in FIG. 1 are by way of example only and may be otherwise.

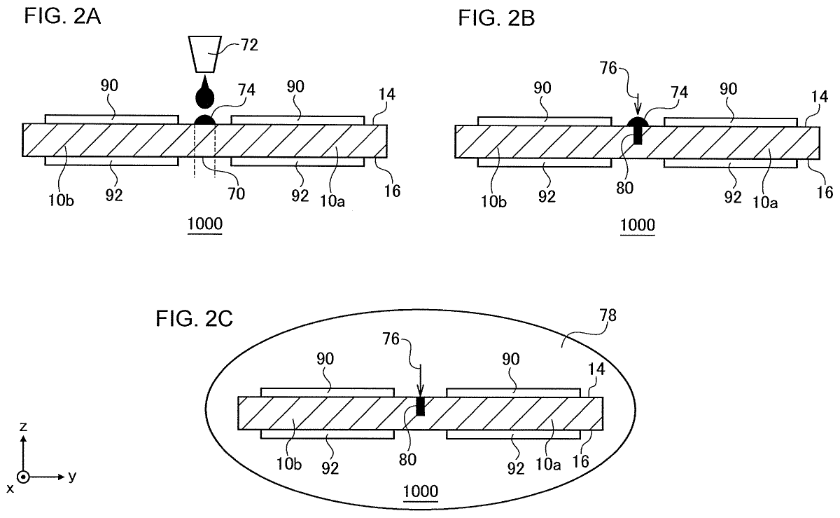

FIG. 2A-2C show an outline of the steps of manufacturing the solar cell 10. In particular, FIGS. 2A-2B show manufacturing steps of solid-state laser doping. The figures show cross-sections of the splittable solar cell 1000 along a line A-A′ of FIG. 1. As shown in FIG. 2A, the splittable solar cell 1000 having a first surface 14 and a second surface 16 facing in opposite directions is prepared. The first surface 14 is the laser irradiation surface facing the positive direction side along the z axis and has the first conductivity type that is the p type or the n type. Meanwhile, the second surface 16 is the laser non-irradiation surface facing the negative direction side along the z axis and has a second conductivity type different from the first conductivity type. Where the first conductivity type is the p type, the second conductivity type is the n type. Where the first conductivity type is the n type, the second conductivity type is the p type. The second surface 16 may have the second conductivity type in its entirety or has the second conductivity type in a part thereof. A surface electrode 90 is provided on the first surface 14 of the splittable solar cell 1000, and a counter electrode 92 is provided on the second surface 16 of the splittable solar cell 1000. The specific structure of the splittable solar cell 1000 will be described in (2) Specific examples.

A laser processing area 70 is provided at the center of the splittable solar cell 1000 in the y axis direction so as to include the splitting line 12 of FIG. 1. The laser processing area 70 is an area expected to be irradiated with a laser. The first surface 14 of the splittable solar cell 1000 is coated with a dopant source 74 as a doping precursor, using a nozzle 72 according to the inkjet method or the dispensing method. The dopant source 74 is, for example, a solid state doping paste and is provided in the laser processing area 70. In a solid state, the dopant source 74 has the first conductivity type, like the first surface 14.

Subsequently, as shown in FIG. 2B, the dopant source 74 is irradiated with a laser 76 from the side of the first surface 14 of the splittable solar cell 1000. Irradiation by the laser 76 forms a high doping concentration area 80 in a portion of the splittable solar cell 1000 toward the first surface 14. Field-effect passivation in the high doping concentration area 80 inhibits a damage from laser irradiation or inhibits reduction in the output. The splittable solar cell 1000 may be split into the first solar cell 10a and the second solar cell 10b by being irradiated with the laser 76 subsequently. Alternatively, a groove for splitting along the splitting line 12 may be formed on the first surface 14 of the splittable solar cell 1000 by irradiating the splittable solar cell 1000 with the laser 76. The splittable solar cell 1000 may be split into the first solar cell 10a and the second solar cell 10b along the groove for splitting.

FIG. 2C shows a manufacturing step of gaseous phase laser doping. The same splittable solar cell 1000 as shown in FIG. 2A is prepared. The splittable solar cell 1000 is provided in an environment of a dopant gas 78 that is a dopant precursor. The dopant gas 78 is in a gaseous state and includes a dopant source. For example, the dopant gas 78 is a BBr₃ gas for p-type doping or a POCl₃ gas for n-type doping. In a gaseous state, the dopant gas 78 has the first conductivity type, like the first surface 14. The first surface 14 of the splittable solar cell 1000 is irradiated with the laser 76 while the dopant gas 78 is being supplied. Irradiation by the laser 76 forms the high doping concentration area 80 a portion of the splittable solar cell 1000 toward the first surface 14. The subsequent step is as already described above so that a description thereof is omitted.

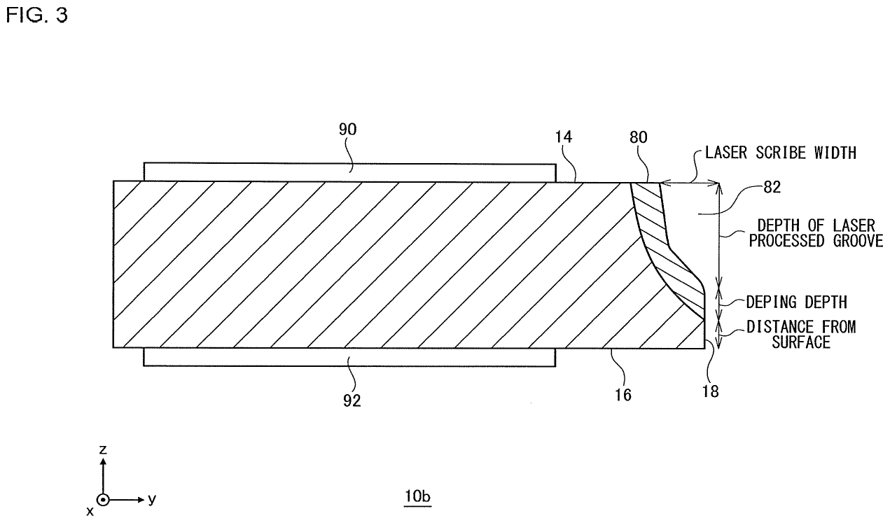

FIG. 3 is a cross-sectional view showing a structure of the second solar cell 10b. The figure shows the second solar cell 10b split according to FIGS. 2A-2C. The first surface 14, the second surface 16, the surface electrode 90, and the counter electrode 92 are as described above, and a description thereof is omitted. A side surface 18 is provided between the first surface 14 and the second surface 16 and extends in the direction of thickness of the splittable solar cell 1000. Irradiation by the laser 76 forms a laser processing groove 82 in such a manner that the corner of the second solar cell 10b is scraped. The width of the laser processing groove 82 is the laser scribing width and is configured to be not less than 10 μm and not more than 100 μm. Further, the depth of the laser processing groove 82 is configured to be in the range of, for example, not less than 25% and not more than 75% of the thickness of the solar cell 10. It is preferable that the depth of the laser processing groove 82 be configured to be in the range of not less than 30% and not more than 50%.

The high doping concentration area 80 is provided along the laser processing groove 82 in a portion of the side surface 18 toward the first surface 14. As described above, the high doping concentration area 80 has the first conductivity type, like the first surface 14. This means that the polarity of the high doping concentration area 80 is opposite to the second conductivity type included in the second surface 16. The high doping concentration area 80 is denoted as the first area, and the portion of the side surface 18 located toward the second surface 16 and outside the high doping concentration area 80 is denoted as the second area. The first impurity peak doping concentration of the first conductivity type in the high doping concentration area 80, i.e., in the first area, is not less than 1019 cm⁻³ and not more than 1021 cm⁻³, and the half width of the doping profile is not less than 0.1 μm and not more than 10 μm. Meanwhile, the first impurity doping concentration in the second area is equal to or less than 1016 cm⁻³, which is defined as the second impurity concentration of the first conductivity type. In this way, the first impurity concentration is higher than the second impurity concentration. Further, the closer to the first surface 14, the higher the impurity concentration, and the closer to the second surface 16, the lower the impurity concentration. Further, the closer to the side surface 18 formed with the laser processing groove 82, the higher the impurity concentration, and the farther from the side surface 18, the lower the impurity concentration.

The length of the second area from the second surface 16 in the direction of thickness of the solar cell 10, i.e., the distance from the surface, is configured to be 10% of the thickness of the solar cell 10 or larger. This is to prevent a leak path to the second surface 16 from being created due to the high doping concentration area 80.

### (2) SPECIFIC EXAMPLES

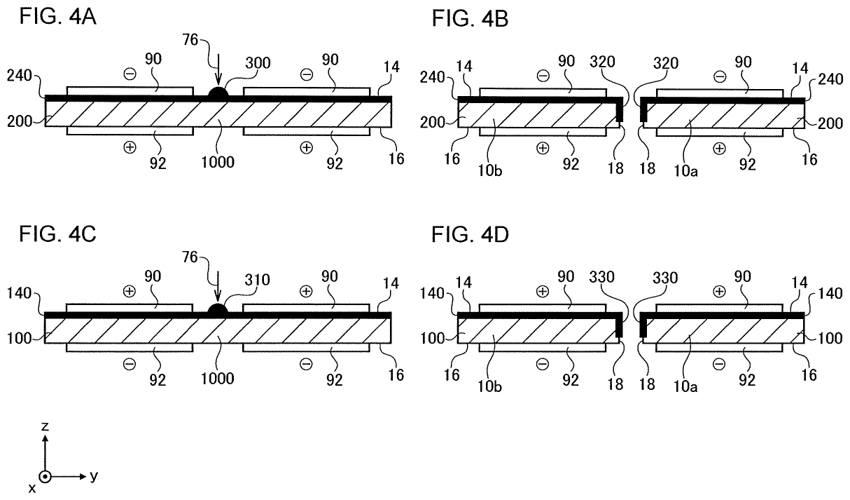

FIGS. 4A-4D show specific examples of the steps of manufacturing the solar cell 10. FIGS. 4A-4B show that a p-type semiconductor substrate 200 and an n-type semiconductor layer 240 are included in the splittable solar cell 1000 and the solar cell 10. More specifically, the n-type semiconductor layer 240 will include the first surface 14, and the p-type semiconductor substrate 200 will include the second surface 16 by stacking the n-type semiconductor layer 240 on the laser irradiation surface side of the p-type semiconductor substrate 200. The first conductivity type that the n-type semiconductor layer 240 has is the n type, and the second conductivity type that the p-type semiconductor substrate 200 has is the p type. Referring to FIG. 4A, an n-type dopant source 300 of the first conductivity type like the n-type semiconductor layer 240 is provided on the n-type semiconductor layer 240, and the n-type dopant source 300 is irradiated with the laser 76. In other words, the laser 76 irradiates the pn junction side. FIG. 4B shows the first solar cell 10a and the second solar cell 10b produced by splitting the splittable solar cell 1000. An n⁺⁺ highly doped area 320 is produced by field-effect passivation on the side surface 18 of the first solar cell 10a and the second solar cell 10b toward the first surface 14. The n⁺⁺ highly doped area 320 corresponds to the high doping concentration area 80.

FIGS. 4C-4D show that an n-type semiconductor substrate 100 and a p-type semiconductor layer 140 are included in the splittable solar cell 1000 and the solar cell 10. More specifically, the p-type semiconductor layer 140 will include the first surface 14, and the n-type semiconductor substrate 100 will include the second surface 16 by stacking the p-type semiconductor layer 140 on the laser irradiation surface side of the n-type semiconductor substrate 100. The first conductivity type that the p-type semiconductor layer 140 has is the p type, and the second conductivity type that the n-type semiconductor substrate 100 has is the n type. Referring to FIG. 4C, a p-type dopant source 310 of the first conductivity type like the p-type semiconductor layer 140 is provided on the p-type semiconductor layer 140, and the p-type dopant source 310 is irradiated with the laser 76. In other words, the laser 76 irradiates the pn junction side. FIG. 4D shows the first solar cell 10a and the second solar cell 10b produced by splitting the splittable solar cell 1000. A p⁺⁺ highly doped area 330 is produced by field-effect passivation on the side surface 18 of the first solar cell 10a and the second solar cell 10b toward the first surface 14. The p⁺⁺ highly doped area 330 corresponds to the high doping concentration area 80.

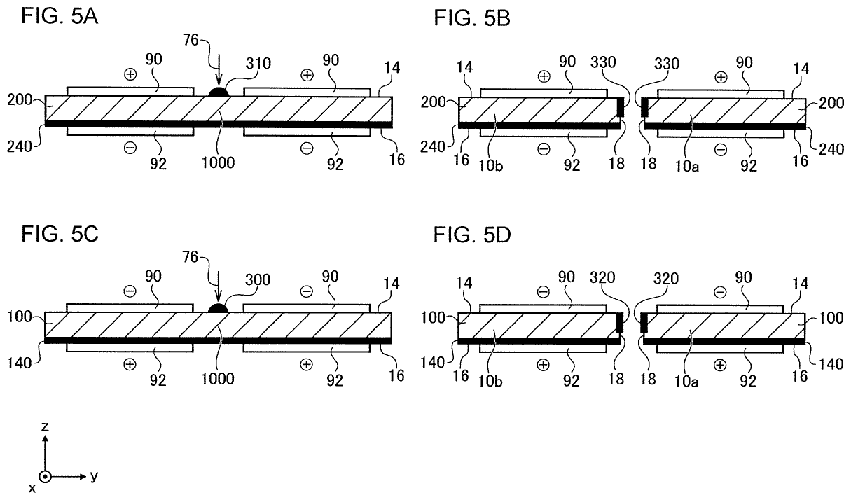

FIGS. 5A-5D show further specific examples of the steps of manufacturing the solar cell 10. FIGS. 5A-5B show that the p-type semiconductor substrate 200 and the n-type semiconductor layer 240 are included in the splittable solar cell 1000 and the solar cell 10. More specifically, the p-type semiconductor substrate 200 will include the first surface 14, and the n-type semiconductor layer 240 will include the second surface 16 by stacking the n-type semiconductor layer 240 on the laser non-irradiation surface side of the p-type semiconductor substrate 200. The first conductivity type that the p-type semiconductor substrate 200 has is the p type, and the second conductivity type that the n-type semiconductor layer 240 has is the n type. Referring to FIG. 5A, the p-type dopant source 310 of the first conductivity type like the p-type semiconductor substrate 200 is provided on the p-type semiconductor substrate 200, and the p-type dopant source 310 is irradiated with the laser 76. In other words, the laser 76 irradiates the side opposite to the pn junction. FIG. 5B shows the first solar cell 10a and the second solar cell 10b produced by splitting the splittable solar cell 1000. The p⁺⁺ highly doped area 330 is produced by field-effect passivation on the side surface 18 of the first solar cell 10a and the second solar cell 10b toward the first surface 14.

FIGS. 5C-5D show that the n-type semiconductor substrate 100 and the p-type semiconductor layer 140 are included in the splittable solar cell 1000 and the solar cell 10. More specifically, the n-type semiconductor substrate 100 will include the first surface 14, and the p-type semiconductor layer 140 will include the second surface 16 by stacking the p-type semiconductor layer 140 on the laser non-irradiation surface side of the n-type semiconductor substrate 100. The first conductivity type that the n-type semiconductor substrate 100 has is the n type, and the second conductivity type that the p-type semiconductor layer 140 has is the p type. Referring to FIG. 5C, the n-type dopant source 300 of the first conductivity type like the n-type semiconductor substrate 100 is provided on the n-type semiconductor substrate 100, and the n-type dopant source 300 is irradiated with the laser 76. In other words, the laser 76 irradiates the side opposite to the pn junction. FIG. 5D shows the first solar cell 10a and the second solar cell 10b produced by splitting the splittable solar cell 1000. The n⁺⁺ highly doped area 320 is produced by field-effect passivation on the side surface 18 of the first solar cell 10a and the second solar cell 10b toward the first surface 14.

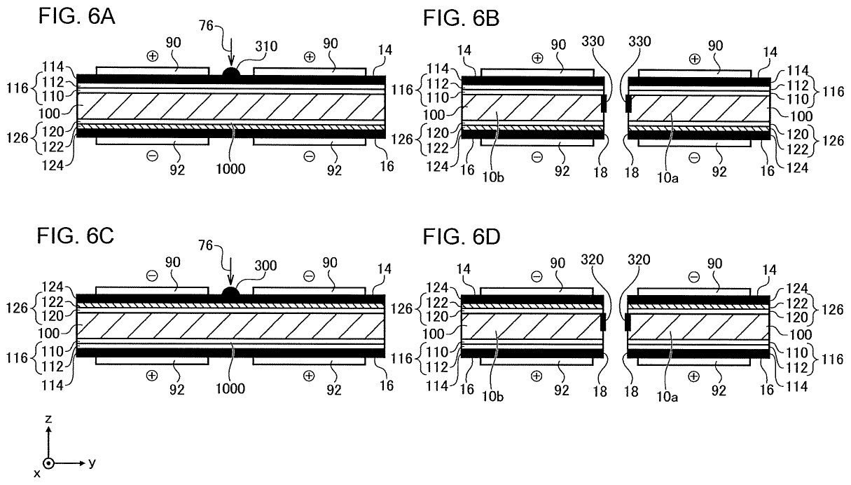

FIGS. 6A-6D show still further specific examples of the steps of manufacturing the solar cell 10. Each of these figures shows a structure of a heterojunction cell. Referring to FIG. 6A, an intrinsic amorphous semiconductor layer 110, a p-type amorphous semiconductor layer 112, and a p-side transparent conductive film layer 114 are provided in the stated order on the laser irradiation surface side of the n-type semiconductor substrate 100. The intrinsic amorphous semiconductor layer 110 and the p-type amorphous semiconductor layer 112 are included in a p-type semiconductor layer 116. The p-side transparent conductive film layer 114 is a translucent conductive film made of ITO (Indium Tin Oxide), etc. Further, an intrinsic amorphous semiconductor layer 120, an n-type amorphous semiconductor layer 122, and an n-side transparent conductive film layer 124 are provided in the stated order on the laser non-irradiation surface side of the n-type semiconductor substrate 100. The intrinsic amorphous semiconductor layer 120 and the n-type amorphous semiconductor layer 122 are included in an n-type semiconductor layer 126.

The p-side transparent conductive film layer 114 or the p-type semiconductor layer 116 includes the first surface 14, and the n-side transparent conductive film layer 124 or the n-type semiconductor layer 126 includes the second surface 16. The first conductivity type that the p-type semiconductor layer 116 has is the p type, and the second conductivity type that the n-type semiconductor layer 126 has is the n type. Referring to FIG. 6A, the p-type dopant source 310 of the first conductivity type like the p-type semiconductor layer 116 is provided on the p-type semiconductor layer 116, and the p-type dopant source 310 is irradiated with the laser 76. In other words, the laser 76 irradiates the pn junction side. FIG. 6B shows the first solar cell 10a and the second solar cell 10b produced by splitting the splittable solar cell 1000. The p⁺⁺ highly doped area 330 is produced by field-effect passivation on the side surface 18 of the first solar cell 10a and the second solar cell 10b toward the first surface 14.

Referring to FIG. 6C, the intrinsic amorphous semiconductor layer 120, the n-type amorphous semiconductor layer 122, and the n-side transparent conductive film layer 124 are provided in the stated order on the laser irradiation surface side of the n-type semiconductor substrate 100. The intrinsic amorphous semiconductor layer 120 and the n-type amorphous semiconductor layer 122 are included in the n-type semiconductor layer 126. Further, the intrinsic amorphous semiconductor layer 110, the p-type amorphous semiconductor layer 112, and the p-side transparent conductive film layer 114 are provided in the stated order on the laser non-irradiation surface side of the n-type semiconductor substrate 100. The intrinsic amorphous semiconductor layer 110 and the p-type amorphous semiconductor layer 112 are included in the p-type semiconductor layer 116. The n-side transparent conductive film layer 124 or the n-type semiconductor layer 126 includes the first surface 14, and the p-side transparent conductive film layer 114 or the p-type semiconductor layer 116 includes the second surface 16. The first conductivity type that the n-type semiconductor layer 126 has is the n type, and the second conductivity type that the p-type semiconductor layer 116 has is the p type. Referring to FIG. 6C, the n-type dopant source 300 of the first conductivity type like the n-type semiconductor layer 126 is provided on the n-type semiconductor layer 126, and the n-type dopant source 300 is irradiated with the laser 76. In other words, the laser 76 irradiates the side opposite to the pn junction. FIG. 6D shows the first solar cell 10a and the second solar cell 10b produced by splitting the splittable solar cell 1000. The n⁺⁺ highly doped area 320 is produced by field-effect passivation on the side surface 18 of the first solar cell 10a and the second solar cell 10b toward the first surface 14.

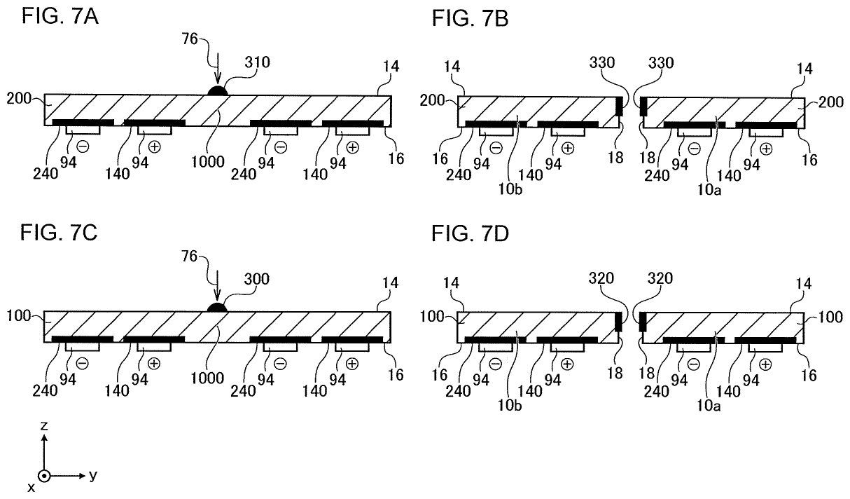

FIGS. 7A-7D show still further specific examples of the steps of manufacturing the solar cell 10. The figures show a structure of an IBC (Interdigitated Back Contact) cell. FIGS. 7A-7B show that the p-type semiconductor substrate 200, the p-type semiconductor layer 140, and the n-type semiconductor layer 240 are included in the splittable solar cell 1000 and the solar cell 10. More specifically, the p-type semiconductor substrate 200 will include the first surface 14, and the n-type semiconductor layer 240 will include the second surface 16 by stacking the p-type semiconductor layer 140 and the n-type semiconductor layer 240 on the laser non-irradiation surface side of the p-type semiconductor substrate 200. The first conductivity type that the p-type semiconductor substrate 200 has is the p type, and the second conductivity type that the n-type semiconductor layer 240 has is the n type. A collecting electrode 94 is provided on the second surface 16. Referring to FIG. 7A, the p-type dopant source 310 of the first conductivity type like the p-type semiconductor substrate 200 is provided on the p-type semiconductor substrate 200, and the p-type dopant source 310 is irradiated with the laser 76. In other words, the laser 76 irradiates the side opposite to the pn junction. FIG. 7B shows the first solar cell 10a and the second solar cell 10b produced by splitting the splittable solar cell 1000. The p⁺⁺ highly doped area 330 is produced by field-effect passivation on the side surface 18 of the first solar cell 10a and the second solar cell 10b toward the first surface 14.

FIGS. 7C-7D show that the n-type semiconductor substrate 100, the p-type semiconductor layer 140, and the n-type semiconductor layer 240 are included in the splittable solar cell 1000 and the solar cell 10. More specifically, the n-type semiconductor substrate 100 will include the first surface 14, and the p-type semiconductor layer 140 will include the second surface 16 by stacking the p-type semiconductor layer 140 and the n-type semiconductor layer 240 on the laser non-irradiation surface side of the n-type semiconductor substrate 100. The first conductivity type that the n-type semiconductor substrate 100 has is the n type, and the second conductivity type that the p-type semiconductor layer 140 has is the p type. Referring to FIG. 7C, the n-type dopant source 300 of the first conductivity type like the n-type semiconductor substrate 100 is provided on the n-type semiconductor substrate 100, and the n-type dopant source 300 is irradiated with the laser 76. In other words, the laser 76 irradiates the side opposite to the pn junction. FIG. 7D shows the first solar cell 10a and the second solar cell 10b produced by splitting the splittable solar cell 1000. The n⁺⁺ highly doped area 320 is produced by field-effect passivation on the side surface 18 of the first solar cell 10a and the second solar cell 10b toward the first surface 14.

### (3) STRUCTURE OF A SOLAR CELL MODULE

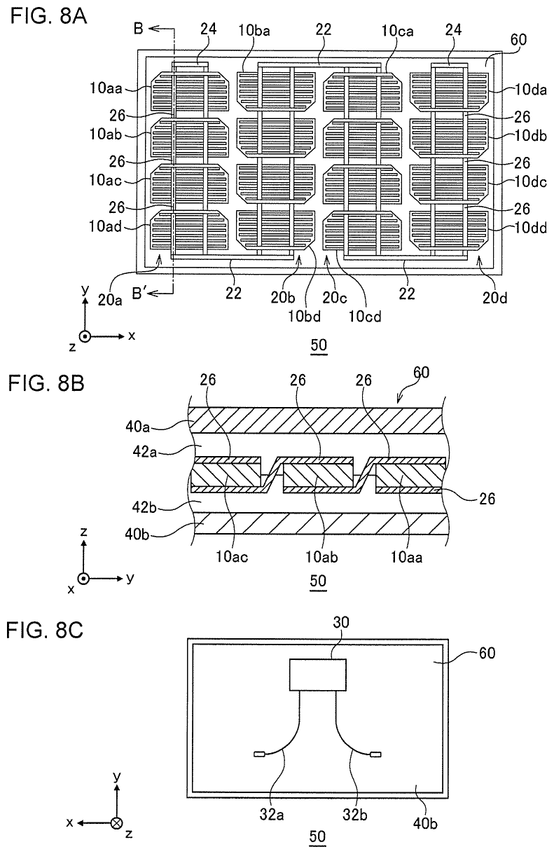

FIGS. 8A-8C show a structure of a solar cell module 50 including the solar cell 10. FIG. 8A is a plan view of the solar cell module 50 as viewed from the light receiving surface side. A frame is attached to the solar cell module 50 so as to surround a solar cell panel 60. The solar cell panel 60 includes an 11th solar cell 10aa, . . . , a 44th solar cell 10dd, which are generically referred to as solar cells 10, inter-string wiring members 22, string-end wiring members 24, and inter-cell wiring members 26. For example, the laser irradiation surface corresponds to a light receiving surface, and the laser non-irradiation surface corresponds to a back surface.

Each solar cell 10 is produced by splitting the splittable solar cell 1000 as described so far. A plurality of finger electrodes extending in the x axis direction in a mutually parallel manner and a plurality of (e.g., two) bus bar electrodes extending in the y axis direction to be orthogonal to the plurality of finger electrodes are disposed on the light receiving surface and the back surface of each solar cell 10. The bus bar electrodes connect the plurality of finger electrodes to each other. The bus bar electrode and the finger electrode correspond to the p-side collecting electrode and the n-side collecting electrode.

The plurality of solar cells 10 are arranged in a matrix on the x-y plane. By way of example, four solar cells 10 are arranged in the x axis direction, and four solar cells are arranged in the y axis direction. The number of solar cells 10 arranged in the x axis direction and the number of solar cells 10 arranged in the y axis direction are not limited to the examples above. The four solar cells 10 arranged and disposed in the y axis direction are connected in series by the inter-cell wiring member 26 so as to form one solar cell string 20. For example, by connecting the 11th solar cell 10aa, a 12th solar cell 10ab, a 13th solar cell 10ac, and a 14th solar cell 10ad, a first solar cell string 20a is formed. The other solar cell strings 20 (e.g., a second solar cell string 20b through a fourth solar cell string 20d) are similarly formed. As a result, the four solar cell strings 20 are arranged in parallel in the x axis direction.

In order to form the solar cell strings 20, the inter-cell wiring members 26 connect the bus bar electrode on the light receiving surface side of one of adjacent solar cells 10 to the bus bar electrode on the back surface side of the other solar cell 10. For example, the two inter-cell wiring members 26 for connecting the 11th solar cell 10aa and the 12th solar cell 10ab electrically connect the bus bar electrode on the light receiving surface side of the 11th solar cell 10aa and the bus bar electrode on the back surface side of the 12th solar cell 10ab.

Each of the plurality of inter-string wiring members 22 extends in the x axis direction and is electrically connected to two adjacent solar cell strings 20. For example, the inter-string wiring member 22 disposed farther on the positive direction side along the y axis than the plurality of solar cells 10 connects the 21st solar cell 10ba in the second solar cell string 20b and the 31st solar cell 10ca in the third solar cell string 20c. The same is also true of the other inter-string wiring members 22. As a result, the plurality of solar cell strings 20 are connected in series. The string-end wiring member 24 is connected to the solar cells 10 (e.g., the 11th solar cell 10aa and the 41st solar cell 10da) at the ends of the plurality of solar cell strings 20 connected in series. The string-end wiring member 24 is connected to a terminal box (not shown).

FIG. 8B is a cross-sectional view of the solar cell module 50 and is a B-B′ cross-sectional view of FIG. 8A. The solar cell panel 60 in the solar cell module 50 includes the 11th solar cell 10aa, the 12th solar cell 10ab, the 13th solar cell 10ac, which are generically referred to as solar cells 10, the inter-cell wiring member 26, a first protective member 40a, a second protective member 40b, which are generically referred to as protective members 40, a first encapsulant 42a, a second encapsulant 42b, which are generically referred to as encapsulants 42. The top of FIG. 8B corresponds to the light receiving surface side, and the bottom corresponds to the back surface side.

The first protective member 40a is disposed on the light receiving surface side of the solar cell panel 60 and protects the surface of the solar cell panel 60. The first protective member 40a is formed by using a translucent and water shielding glass, translucent plastic, etc. and is formed in a rectangular shape. In this case, it is assumed that glass is used. The first encapsulant 42a is stacked on the back surface side of the first protective member 40a. The first encapsulant 42a is disposed between the first protective member 40a and the solar cell 10 and adhesively bonds the first protective member 40a and the solar cell 10. For example, a thermoplastic resin film of polyolefin, EVA, polyvinyl butyral (PVB), polyimide, or the like may be used as the first encapsulant 42a. A thermosetting resin may alternatively be used. The first encapsulant 42a is formed by a translucent, rectangular sheet member having a surface of substantially the same dimension as the x-y plane in the first protective member 40a.

The second encapsulant 42b is stacked on the back surface side of the first encapsulant 42a. The second encapsulant 42b encapsulates the plurality of solar cells 10, the inter-cell wiring members 26, etc. between the second encapsulant 42b and the first encapsulant 42a. The second encapsulant 42b may be made of a material similar to that of the first encapsulant 42a. Alternatively, the second encapsulant 42b may be integrated with the first encapsulant 42a by heating the members in a laminate cure process.

The second protective member 40b is stacked on the back surface side of the second encapsulant 42b. The second protective member 40b protects the back surface side of the solar cell panel 60 as a back sheet. A resin (e.g., PET) film is used for the second protective member 40b. A stack film having a structure in which an Al foil is sandwiched by resin films, or the like is used as the second protective member 40b.

FIG. 8C is a plan view of the solar cell module 50 as viewed from the back surface side. A box-shaped terminal box 30 is attached to the solar cell panel 60 in the solar cell module 50. A first cable 32a and a second cable 32b are electrically connected to the terminal box 30. The first cable 32a and the second cable 32b output the electric power generated in the solar cell module 50 outside.

According to the embodiment, the dopant source 74 of the first conductivity type is provided on the first surface 14 of the splittable solar cell 1000 having the first conductivity, and the dopant source is irradiated with the laser 76. Therefore, the high doping concentration area 80 is formed on the side surface 18 of the solar cell 10. Further, since the high doping concentration area 80 is formed on the side surface 18 of the solar cell 10, reduction in the output of power generation due to splitting is inhibited by field-effect passivation. Further, the first surface 14 of the splittable solar cell 1000 having the first conductivity type is irradiated with the laser 76 while a dopant gas of the first conductivity type is being supplied so that the high doping concentration area 80 is formed on the side surface 18 of the solar cell 10.

Further, the semiconductor layer and the semiconductor substrate are stacked, the semiconductor layer includes the first surface 14, and the semiconductor substrate includes the second surface 16 so that it is ensured that the conductivity type of the first surface 14 and the conductivity type of the dopant source 74 match. Further, the n-type semiconductor layer 126, the n-type semiconductor substrate 100, and the p-type semiconductor layer 116 are stacked successively, the n-type semiconductor layer 126 includes the first surface 14, and the p-type semiconductor layer 116 includes the second surface 16 so that it is ensured that the conductivity type of the first surface 14 and the conductivity type of the dopant source 74 match.

Further the splittable solar cell 1000 is split into a plurality of solar cells 10 by irradiating the splittable solar cell 1000 with the laser 76 so that the plurality of solar cells 10 are manufactured. Further, the splittable solar cell 1000 is split into the plurality of solar cells 10 along the groove for splitting formed on the first surface 14 of the splittable solar cell 1000 by irradiating the splittable solar cell 1000 with the laser 76 so that the plurality of solar cells 10 are manufactured. Further, the first area is provided on the side surface 18 toward the first surface 14, the second area is provided on the side surface 18 toward the second surface 16, and the first impurity concentration in the first area is higher than the second impurity concentration in the second area so that reduction in the output of power generation due to splitting is inhibited. Further, the length of the second area from the second surface 16 in the direction from the second surface 16 toward the first surface 14 is 10% of the length from the second surface 16 to the first surface 14 or larger so that formation of a leak path is prevented.

A summary of the embodiment is given below. The method of manufacturing a solar cell 10 according to an embodiment of the disclosure includes: preparing a splittable solar cell 1000 in which a first surface 14 having a first conductivity type and a second surface 16 including at least a portion of a second conductivity type different from the first conductivity type face opposite directions; providing a dopant source 74 of the of the first conductivity type on the first surface 14 of the splittable solar cell 1000; and irradiating the dopant source 74 with a laser 76.

Another embodiment of the present disclosure also relates to a method of manufacturing a solar cell 10. The method includes: preparing a splittable solar cell 1000 in which a first surface 14 having a first conductivity type and a second surface 16 including at least a portion of a second conductivity type different from the first conductivity type face opposite directions; and irradiating the first surface 14 of the splittable solar cell 1000 with a laser 76 while supplying a dopant gas 78 of the first conductivity type to the first surface 14.

An n-type semiconductor layer 240 having the first conductivity type and a p-type semiconductor substrate 200 having the second conductivity type may be stacked in the splittable solar cell 1000, and the n-type semiconductor layer 240 may include the first surface 14. The p-type semiconductor substrate 200 includes the second surface 16.

An n-type semiconductor layer 126 having the first conductivity type, an n-type semiconductor substrate 100 having the first conductivity type, and a p-type semiconductor layer 116 having the second conductivity type may be stacked successively in the splittable solar cell 1000, and the n-type semiconductor layer 126 may include the first surface 14. The p-type semiconductor layer 116 includes the second surface 16.

A p-type semiconductor layer 140 having the second conductivity type and an n-type semiconductor substrate 100 having the first conductivity type may be stacked successively in the splittable solar cell 1000, and the p-type semiconductor layer 140 may include the second surface 16. The n-type semiconductor substrate 100 includes the first surface 14.

An n-type semiconductor layer 126 having the second conductivity type, an n-type semiconductor substrate 100 having the second conductivity type, and a p-type semiconductor layer 116 having the first conductivity type may be stacked successively in the splittable solar cell 1000, and the n-type semiconductor layer 126 may include the second surface 16. The p-type semiconductor layer 116 includes the first surface 14.

The method further includes: splitting the the splittable solar cell 1000 into a plurality of solar cells 10 by irradiating the splittable solar cell 1000 with a laser 76.

The method further includes: forming a groove for splitting on the first surface 14 of the splittable solar cell 1000 by irradiating the splittable solar cell 1000 with a laser 76; and splitting the splittable solar cell 1000 along the groove for splitting into a plurality of solar cells 10.

Another embodiment of the present disclosure relates to a solar cell 10. The solar cell 10 includes: a first surface 14 having a first conductivity type; a second surface 16 facing a direction opposite to a direction of the first surface 14 and having at least a portion of a second conductivity type different from the first conductivity type; and a side surface 18 provided between the first surface 14 and the second surface 16. A first area is provided in a portion of the side surface 18 toward the first surface 14, and a second area is provided in a portion toward the second surface 16, and a first impurity concentration of the first conductivity type in the first area is higher than a second impurity concentration of the first conductivity type in the second area.

A length of the second area from the second surface 16 in a direction from the second surface 16 toward the first surface 14 is 10% of a length from the second surface 16 to the first surface 14 or larger.

Another embodiment of the present disclosure relates to a solar cell module 50. The solar cell module 50 includes a plurality of solar cells 10. Each of the plurality of solar cells 10 includes: a first surface 14 having a first conductivity type; a second surface 16 facing a direction opposite to a direction of the first surface 14 and having at least a portion of a second conductivity type different from the first conductivity type; and a side surface 18 provided between the first surface 14 and the second surface 16. A first area is provided in a portion of the side surface 18 toward the first surface 14, and a second area is provided in a portion toward the second surface 16, and a first impurity concentration of the first conductivity type in the first area is higher than a second impurity concentration of the first conductivity type in the second area.

Described above is an explanation of the present disclosure based on an exemplary embodiment. The embodiment is intended to be illustrative only and it will be understood by those skilled in the art that various modifications to constituting elements and processes could be developed and that such modifications are also within the scope of the present disclosure.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A method of manufacturing a solar cell comprising:
preparing a splittable solar cell in which a first surface having a first conductivity type and a second surface including at least a portion of a second conductivity type different from the first conductivity type face opposite directions;
providing a dopant source of the of the first conductivity type on the first surface of the splittable solar cell; and
irradiating the dopant source with a laser.

2. A method of manufacturing a solar cell comprising:
preparing a splittable solar cell in which a first surface having a first conductivity type and a second surface including at least a portion of a second conductivity type different from the first conductivity type face opposite directions; and
irradiating the first surface of the splittable solar cell with a laser while supplying a dopant gas of the first conductivity type to the first surface.

3. The method of manufacturing a solar cell according to claim 1, wherein
a semiconductor layer having the first conductivity type and a semiconductor substrate having the second conductivity type are stacked in the splittable solar cell,
the semiconductor layer includes the first surface, and
the semiconductor substrate includes the second surface.

4. The method of manufacturing a solar cell according to claim 2, wherein
a semiconductor layer having the first conductivity type and a semiconductor substrate having the second conductivity type are stacked in the splittable solar cell,
the semiconductor layer includes the first surface, and
the semiconductor substrate includes the second surface.

5. The method of manufacturing a solar cell according to claim 1, wherein
a first semiconductor layer having the first conductivity type, a semiconductor substrate having the first conductivity type, and a second semiconductor layer having the second conductivity type are stacked successively in the splittable solar cell,
the first semiconductor layer includes the first surface, and
the second semiconductor layer includes the second surface.

6. The method of manufacturing a solar cell according to claim 2, wherein
a first semiconductor layer having the first conductivity type, a semiconductor substrate having the first conductivity type, and a second semiconductor layer having the second conductivity type are stacked successively in the splittable solar cell,
the first semiconductor layer includes the first surface, and
the second semiconductor layer includes the second surface.

7. The method of manufacturing a solar cell according to claim 1, wherein
a semiconductor layer having the second conductivity type and a semiconductor substrate having the first conductivity type are stacked successively in the splittable solar cell,
the semiconductor layer includes the second surface, and
the semiconductor substrate includes the first surface.

8. The method of manufacturing a solar cell according to claim 2, wherein
a semiconductor layer having the second conductivity type and a semiconductor substrate having the first conductivity type are stacked successively in the splittable solar cell,
the semiconductor layer includes the second surface, and
the semiconductor substrate includes the first surface.

9. The method of manufacturing a solar cell according to claim 1, wherein
a first semiconductor layer having the second conductivity type, a semiconductor substrate having the second conductivity type, and a second semiconductor layer having the first conductivity type are stacked successively in the splittable solar cell,
the first semiconductor layer includes the second surface, and
the second semiconductor layer includes the first surface.

10. The method of manufacturing a solar cell according to claim 2, wherein
a first semiconductor layer having the second conductivity type, a semiconductor substrate having the second conductivity type, and a second semiconductor layer having the first conductivity type are stacked successively in the splittable solar cell,
the first semiconductor layer includes the second surface, and
the second semiconductor layer includes the first surface.

11. The method of manufacturing a solar cell according to claim 1, further comprising:
splitting the the splittable solar cell into a plurality of solar cells by irradiating the splittable solar cell with a laser.

12. The method of manufacturing a solar cell according to claim 1, further comprising:
forming a groove for splitting on the first surface of the splittable solar cell by irradiating the splittable solar cell with a laser; and
splitting the splittable solar cell along the groove for splitting into a plurality of solar cells.

13. A solar cell comprising:
a first surface having a first conductivity type;
a second surface facing a direction opposite to a direction of the first surface and having at least a portion of a second conductivity type different from the first conductivity type; and
a side surface provided between the first surface and the second surface, wherein
a first area is provided in a portion of the side surface toward the first surface, and a second area is provided in a portion toward the second surface, and a first impurity concentration of the first conductivity type in the first area is higher than a second impurity concentration of the first conductivity type in the second area.

14. The solar cell according to claim 13, wherein
a length of the second area from the second surface in a direction from the second surface toward the first surface is 10% of a length from the second surface to the first surface or larger.

15. A solar cell module comprising:
a plurality of solar cells, wherein
each of the plurality of solar cells includes:
a first surface having a first conductivity type;
a second surface facing a direction opposite to a direction of the first surface and having at least a portion of a second conductivity type different from the first conductivity type; and
a side surface provided between the first surface and the second surface, wherein
a first area is provided in a portion of the side surface toward the first surface, and a second area is provided in a portion toward the second surface, and a first impurity concentration of the first conductivity type in the first area is higher than a second impurity concentration of the first conductivity type in the second area.
